(19) United States
(12) Patent Application Publication
(10) Pub. No.: US 2020/0183057 A1
(43) Pub. Date: Jun. 11, 2020

(54) METHODS OF FORMING THREE-DIMENSIONAL MICROLENSES FOR IMAGING PIXELS

(71) Applicant: SEMICONDUCTOR COMPONENTS INDUSTRIES, LLC, Phoenix, AZ (US)

(72) Inventors: Ulrich BOETTIGER, Garden City, ID (US); Brian Anthony VAARTSTRA, Nampa, ID (US)

(73) Assignee: SEMICONDUCTOR COMPONENTS INDUSTRIES, LLC, Phoenix, AZ (US)

(21) Appl. No.: 16/214,972

(22) Filed: Dec. 10, 2018

(51) Int. Cl. G02B 3/00; B33Y 10/00; B33Y 80/00; B29D 11/00; G03F 7/00; B41M 3/00

(52) U.S. Cl. CPC G02B 3/0012; B33Y 10/00; B41M 3/003; B29D 11/00298; G03F 7/0005; B33Y 80/00

(57) ABSTRACT

Three-dimensional structures may be formed on a substrate using a propellant that may decompose to form a gaseous byproduct. At least one overlying shell layer may deform due to volumes of gas between the substrate and the shell layer formed by the gaseous byproduct, thereby forming the three-dimensional structures. Multiple layers of propellant and shell layers may be stacked to multi-layered, three-dimensional structures. Propellant with different concentrations and shell layers with different thicknesses and materials may be used to control the shapes formed when the propellant is decomposed. Alternatively, porous layers may be deposited on a substrate and heated to expand volumes of gas between the substrate and the porous layers, thereby forming three-dimensional structures. The three-dimensional structures may be formed as microlenses in imaging sensor pixels, as it may be desired to form an array of microlenses that vary in size, shape, or curvature across one or more pixels.

### BACKGROUND

This relates generally to image sensors and, more particularly, to image sensors having lenses to focus light.

Image sensors are commonly used in electronic devices such as cellular telephones, cameras, and computers to capture images. In a typical arrangement, an electronic device is provided with an array of image pixels arranged in pixel rows and pixel columns. Each image pixel in the array includes a photodiode that is coupled to a floating diffusion region via a transfer gate. Each pixel receives incident photons (light) and converts the photons into electrical signals. Column circuitry is coupled to each pixel column for reading out pixel signals from the image pixels. Image sensors are sometimes designed to provide images to electronic devices using a Joint Photographic Experts Group (JPEG) format.

Conventional image sensors sometimes include a microlens above each pixel. In particular, each of the microlenses may have three-dimensional shapes that vary over the respective pixel. Traditionally, these microlenses may be formed using reflow processes, which rely on carefully selecting materials with surface tensions and viscosities that allow the materials to form appropriate shapes and curvatures or rely on the use of external templates. However, forming microlenses in this way does not allow for flexibility in the shapes of the microlenses or in the resolution of an array of microlenses. Moreover, while three-dimensional structures may be formed from glass bubbles, softening glass requires high temperatures that may damage electronic components.

It would therefore be desirable to provide an improved method of forming microlenses for image sensors.

### BRIEF DESCRIPTION OF THE DRAWINGS

FIG. 1 is a schematic diagram of an illustrative electronic device that may include an image sensor in accordance with an embodiment.

FIG. 2 is a diagram of an illustrative pixel array and associated readout circuitry for reading out image signals from the pixel array in accordance with an embodiment.

FIG. 3 is a cross-sectional side view of illustrative pixels covered with microlenses of varying curvature in accordance with an embodiment.

FIG. 4 is a diagram of illustrative equipment and operations involved in forming various three-dimensional structures over a substrate using propellant in accordance with an embodiment.

FIG. 5 is a flow chart of illustrative steps involved in forming various three-dimensional structures over a substrate using propellant in accordance with an embodiment.

FIG. 6 is a diagram of illustrative equipment and operations involved with forming various three-dimensional structures over a substrate using a low density material in accordance with an embodiment.

FIG. 7 is a flow chart of illustrative steps involved in forming various three-dimensional structures over a substrate using a low density material in accordance with an embodiment.

FIG. 8A is a cross-sectional side view of multiple layers of three-dimensional structures over a substrate in accordance with an embodiment.

FIG. 8B is a cross-sectional side view of three-dimensional structures formed on a curved substrate in accordance with an embodiment.

FIG. 8C is a cross-sectional side view of three-dimensional structures formed on a substrate that is coupled to a component.

### DETAILED DESCRIPTION

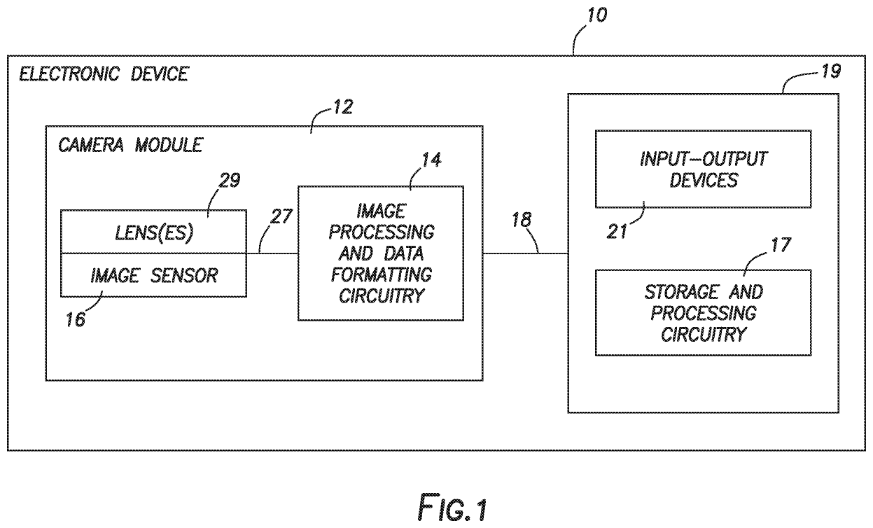

Embodiments of the present invention relate to forming microlenses for image sensors by expanding polymer layers until they have desired shapes and curvatures. An electronic device with a digital camera module is shown in FIG. 1. Electronic device 10 may be a digital camera, a computer, a cellular telephone, a medical device, or other electronic device. Camera module 12 (sometimes referred to as an imaging device) may include image sensor 16 and one or more lenses 29. During operation, lenses 29 (sometimes referred to as optics 29) focus light onto image sensor 16. Image sensor 16 includes photosensitive elements (e.g., pixels) that convert the light into digital data.

Image sensors may have any number of pixels (e.g., hundreds, thousands, millions, or more). A typical image sensor may, for example, have millions of pixels (e.g., megapixels). As examples, image sensor 16 may include bias circuitry (e.g., source follower load circuits), sample and hold circuitry, correlated double sampling (CDS) circuitry, amplifier circuitry, analog-to-digital (ADC) converter circuitry, data output circuitry, memory (e.g., buffer circuitry), address circuitry, etc.

Still and video image data from image sensor 16 may be provided to image processing and data formatting circuitry 14 via path 27. Image processing and data formatting circuitry 14 may be used to perform image processing functions such as automatic focusing functions, depth sensing, data formatting, adjusting white balance and exposure, implementing video image stabilization, face detection, etc. For example, during automatic focusing operations, image processing and data formatting circuitry 14 may process data gathered by phase detection pixels in image sensor 16 to determine the magnitude and direction of lens movement (e.g., movement of lens 29) needed to bring an object of interest into focus.

Image processing and data formatting circuitry 14 may also be used to compress raw camera image files if desired (e.g., to Joint Photographic Experts Group or JPEG format). In a typical arrangement, which is sometimes referred to as a system on chip (SOC) arrangement, camera sensor 16 and image processing and data formatting circuitry 14 are implemented on a common integrated circuit. The use of a single integrated circuit to implement camera sensor 16 and image processing and data formatting circuitry 14 can help to reduce costs. This is, however, merely illustrative. If desired, camera sensor 14 and image processing and data formatting circuitry 14 may be implemented using separate integrated circuits. If desired, camera sensor 16 and image processing circuitry 14 may be formed on separate semiconductor substrates. For example, camera sensor 16 and image processing circuitry 14 may be formed on separate substrates that have been stacked.

Camera module 12 may convey acquired image data to host subsystems 19 over path 18 (e.g., image processing and data formatting circuitry 14 may convey image data to subsystems 19). Electronic device 10 typically provides a user with numerous high-level functions. In a computer or advanced cellular telephone, for example, a user may be provided with the ability to run user applications. To implement these functions, host subsystem 19 of electronic device 10 may include storage and processing circuitry 17 and input-output devices 21 such as keypads, input-output ports, joysticks, and displays. Storage and processing circuitry 17 may include volatile and nonvolatile memory (e.g., random-access memory, flash memory, hard drives, solid state drives, etc.). Storage and processing circuitry 17 may also include microprocessors, microcontrollers, digital signal processors, application specific integrated circuits, or other processing circuits.

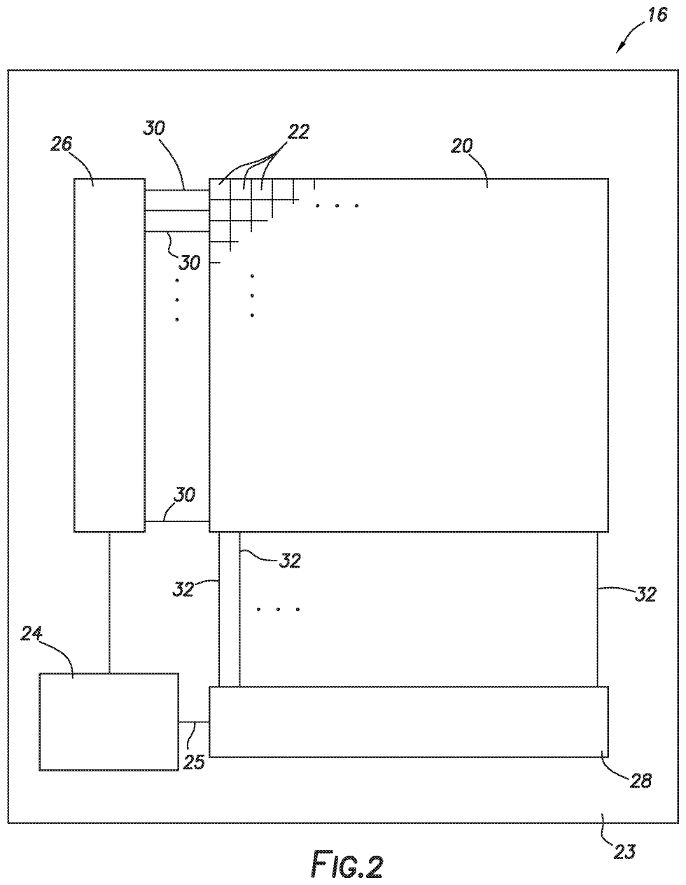

As shown in FIG. 2, image sensor 16 may include pixel array 20 containing image sensor pixels 22 arranged in rows and columns (sometimes referred to herein as image pixels or pixels) and control and processing circuitry 24 (which may include, for example, image signal processing circuitry). Array 20 may contain, for example, hundreds or thousands of rows and columns of image sensor pixels 22. Control circuitry 24 may be coupled to row control circuitry 26 and image readout circuitry 28 (sometimes referred to as column control circuitry, readout circuitry, processing circuitry, or column decoder circuitry). Pixel array 20, control and processing circuitry 24, row control circuitry 26, and image readout circuitry 28 may be formed on a substrate 23. If desired, some or all of the components of image sensor 16 may instead be formed on substrates other than substrate 23, which may be connected to substrate 23, for instance, through wire bonding or flip-chip bonding.

Row control circuitry 26 may receive row addresses from control circuitry 24 and supply corresponding row control signals such as reset, row-select, charge transfer, dual conversion gain, and readout control signals to pixels 22 over row control paths 30. One or more conductive lines such as column lines 32 may be coupled to each column of pixels 22 in array 20. Column lines 32 may be used for reading out image signals from pixels 22 and for supplying bias signals (e.g., bias currents or bias voltages) to pixels 22. If desired, during pixel readout operations, a pixel row in array 20 may be selected using row control circuitry 26 and image signals generated by image pixels 22 in that pixel row can be read out along column lines 32.

Image readout circuitry 28 may receive image signals (e.g., analog pixel values generated by pixels 22) over column lines 32. Image readout circuitry 28 may include sample-and-hold circuitry for sampling and temporarily storing image signals read out from array 20, amplifier circuitry, analog-to-digital conversion (ADC) circuitry, bias circuitry, column memory, latch circuitry for selectively enabling or disabling the column circuitry, or other circuitry that is coupled to one or more columns of pixels in array 20 for operating pixels 22 and for reading out image signals from pixels 22. ADC circuitry in readout circuitry 28 may convert analog pixel values received from array 20 into corresponding digital pixel values (sometimes referred to as digital image data or digital pixel data). Image readout circuitry 28 may supply digital pixel data to control and processing circuitry 24 over path 25 for pixels in one or more pixel columns.

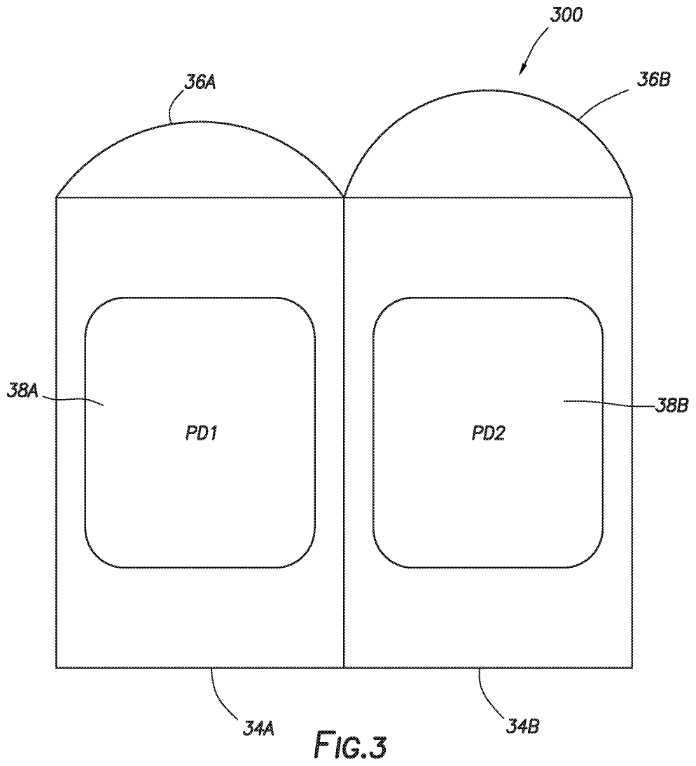

Each of pixels 22 may be overlapped by one or more microlenses that direct light incident on the pixels to respective photosensitive regions. The microlenses may have different shapes or different curvatures to direct the light as desired in each pixel. An example of this arrangement is shown in FIG. 3.

An illustrative portion 300 of pixel array 20 is shown in FIG. 3. In particular, portion 300 may be two pixels of array 20, each of the pixels having a respective photosensitive region. As shown in FIG. 3, pixel 34A may have a first photosensitive region, photodiode 38A, and pixel 34B may have a second photosensitive region, photodiode 38B. Pixels 34A and 34B may be overlapped by respective microlenses 36A and 36B. Microlens 36A may direct incident light onto photodiode 38A, and microlens 36B may direct incident light onto photodiode 38B.

As shown in FIG. 3, microlenses 36A and 36B may have different shapes and/or curvatures. In particular, microlenses 36A and 36B may have spheroidal or semi-cylindrical shapes with different radii. As an example, microlens 36A may have a spheroidal shape with a first radius and microlens 36B may have a semi-cylindrical shape with a second radius that is less than the first radius. However, this is merely illustrative. In general, the shapes and curvatures of microlenses 36A and 36B may be adjusted to ensure that light incident on microlenses 36A and 36B reaches the desired portions of photodiodes 34A and 34B.

Although FIG. 3 is shown as having two pixels 34A and 34B that correspond to respective microlenses 36A and 36B, this is merely illustrative. Portion 300 of pixel array 22 may instead be a single pixel having left and right portions 34A and 34B with respective photodiodes 38A and 38B. In this arrangement, microlenses 36A and 36B may have different shapes and curvatures to direct light into the desired portion of pixel 300. For example, it may be desired for microlens 36A to refract light to a greater degree than microlens 36B, thereby directing more light to photodiode 38B. However, this is merely illustrative. Microlenses 36A and 36B may have any desired shapes and curvatures.

FIG. 3 depicts two microlenses 36A and 36B, each overlapping a respective photodiode 38A and 38B. However, this is merely illustrative. More than one microlens, more than two microlenses, or fewer than five microlenses may overlap each photodiode. In general, any desired number of microlenses may be used.

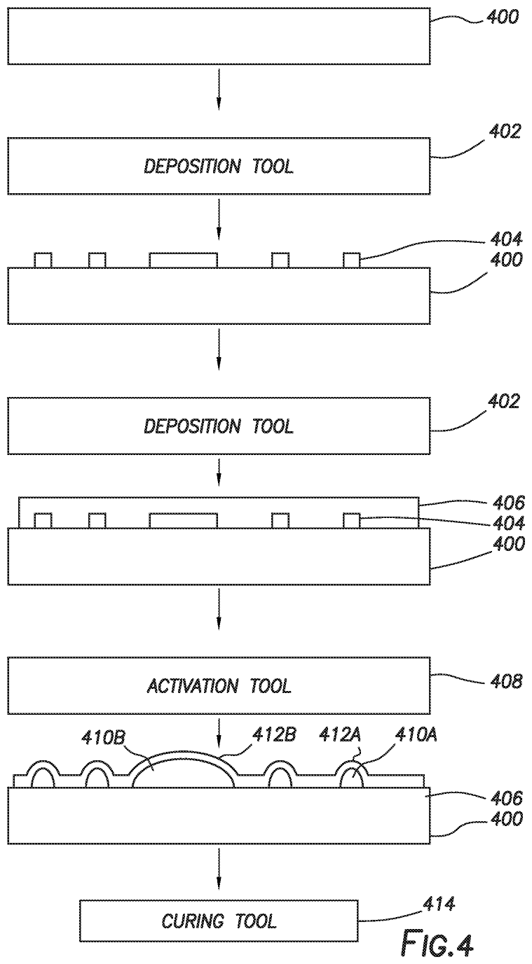

Although microlenses may be formed by using a reflow process or a mold or other external template, this does not provide flexibility in the shapes and curvatures of the microlenses over each pixel. An illustrative method of forming microlenses of various shapes and curvatures is shown in FIG. 4.

As shown in FIG. 4, deposition tool 402 may be used to deposit propellant 404 onto substrate 400. As an example, substrate 400 may be glass. However, any desired material may be used for substrate 400. Deposition tool 402 may use ink jet printing, imprinting, three-dimensional printing (e.g., 3D printing), or spin coating to deposit propellant 404. If propellant 404 is deposited using spin coating or another uniform deposition process, deposition tool 402 may also perform patterning. For example, deposition tool 402 may use lithography to remove portions of propellant 404. However, these processes are merely illustrative. In general, deposition tool 402 may use any desired deposition and patterning processes to apply propellant 404 to substrate 400.

Propellant 404 may be azobisisobutyronitrile (AIBN), other azo compounds, other nitrile compounds, or other decomposable compound. Azo compounds, which may release nitrogen gas upon activation (e.g., through heating and/or exposure to other external energy), allow for the formation of bubbles of nitrogen gas under a material that may deform to create three-dimensional structures. However, the use of azo compounds is merely illustrative. In general, any desired compound that produces a gaseous byproduct may be used as propellant 404.

Although propellant 404 has been described as being a single material applied to substrate 400, propellant 404 may have portions formed from different materials. For example, propellant 404 may be patterned into different regions, each region formed from a different propellant compound. Alternatively, propellant 404 may be patterned into different regions, and some of the regions may be formed from azobisisobutyronitrile while other regions are formed from other compounds. Moreover, each patterned portion of propellant 404 may be formed from different concentrations of materials. However, this is merely illustrative. In general, any desired materials may be used in any combination and/or concentration to form propellant 404.

After propellant 404 has been deposited and patterned on substrate 400, shell layer 406 may be deposited over substrate 400 and propellant 404 using deposition tool 402 (or a different deposition tool, if desired). Deposition tool 402 may use ink jet printing, imprinting, 3D printing, or spin coating to deposit shell layer 406. If shell layer 406 is deposited using spin coating or another uniform deposition process, deposition tool 402 may also perform patterning. For example, deposition tool 402 may use lithography to remove portions of shell layer 406, if desired. However, these processes are merely illustrative. In general, deposition tool 402 may use any desired deposition and patterning processes to apply shell layer 406 to substrate 400. Moreover, the process used to deposit shell layer 406 may be the same as or different from the process used to deposit propellant 404.

In general, shell layer 406 may be formed from any desired material, including organic material, inorganic material, or hybrid material (e.g., material that is both organic and inorganic). Shell layer 406 may be elastomeric and have deformable properties at room temperature, or shell layer 406 may be polymeric and require heating to a glass transition temperature to become deformable. However, these properties are merely illustrative. Any desired deformable material may be used to form shell layer 406.

After shell layer 406 has been deposited over propellant 404 and substrate 404, activation tool 408 may be used to activate propellant 404. Activation tool 408 may expose propellant 404 to heat, ultraviolet energy, infrared energy, or microwave energy, or combinations thereof, as examples. Activation tool 408 may apply energy across all of propellant 404 simultaneously, or activation tool 408 may apply the energy directionally and locally (e.g., using a lithography mask) for enhanced control and selectivity. If propellant 404 has been formed from different materials, the different materials may require different amounts of energy (e.g., activation energies) to activate the propellant. In this case, activation tool 408 may apply different activation energies sequentially to activate different portions of propellant 404. However, these methods are merely illustrative. In general, activation tool 408 may use any desired process to activate propellant 404, and the process used may be dependent on the material used as the propellant.

Depending on the material used for shell layer 406, activation tool 408 may heat shell layer 406 and/or control ambient pressure while activating propellant 404. As an example, if shell layer 406 is polymeric, activation tool 408 may maintain the temperature of shell layer 406 above a glass transition temperature so that shell layer 406 deforms when propellant 404 is activated. Additionally or alternatively, the ambient pressure may be reduced, thereby creating a vacuum that surrounds shell layer 406. The vacuum may further aid in causing the desired deformation of porous layer 406. The deformation of shell layer 406 may allow for the formation of three-dimensional structures 412. However, activation tool 408 may control the temperature of shell layer 406 and the ambient pressure in any desired manner. For example, activation tool 408 may raise the temperature of shell layer 406 past its glass transition temperature and activate propellant 404 while it is cooling, or activation tool 408 may heat shell layer 406 through substrate 400.

As an example, activation tool 408 may heat propellant 404 to between 70° C. and 100° C. to decompose propellant 404 and produce gaseous byproducts. However, this is merely illustrative. Propellant 404 may be heated to more than 70° C., more than 80° C., less than 250° C., or any other desired temperature to decompose the propellant material. Advantageously, propellant 404 may decompose at a temperature that will not harm surrounding components (e.g., substrate 400 or other component if the layers of FIG. 4 have been assembled into an electronic device prior to the propellant's activation). Propellant 404 may therefore be formed from a material that decomposes at less than 250° C., less than 300° C., more than 70° C., or less than 350° C., as examples.

After propellant 404 has been activated by activation tool 408, the gas released by the decomposed propellant forms pockets of gas 410 between substrate 400 and shell layer 406. Pockets of gas 410 may be also be referred to herein as bubbles or balloons. As discussed above, shell layer 406 may be formed from an elastomer capable of deformation, a polymer that may be deformed when heated above a glass transition temperature, or other deformable material. Shell layer 406 may therefore deform due to the gas released by propellant 404 as it decomposes. The deformation of shell layer 46 may form three-dimensional structures 412 over substrate 400. Three-dimensional structures 412 may have any desired shape, such as hemispherical or semi-cylindrical as examples.

As shown in FIG. 4, first pocket of gas 410A may be smaller than second pocket gas 410B, thereby forming a first three-dimensional structure 412A that is smaller than second three-dimensional structure 412B. First three-dimensional structure 412A may also have a different shape and/or curvature than second three-dimensional structure 412B. As discussed above, the shapes, sizes, and curvatures of three-dimensional structures 412 may result from using different amounts of propellant 404, different concentrations of propellant 404, or different materials for propellant 404 in different locations on substrate 400. As an example, more propellant 404 may have been deposited on substrate 400 in a location corresponding to second three-dimensional structure 412B than in a location corresponding to first three-dimensional structure 412A. However, this is merely illustrative. The different shapes, sizes, and curvatures of three-dimensional structures 412 may be formed due to any desired characteristics of propellant 404.

If desired, curing tool 414 may be used to maintain three-dimensional structures 412 in a three-dimensional shape. For example, if shell layer 406 is a polymer that has been heated above its glass transition temperature, curing tool 414 may harden shell layer 406 after three-dimensional structures 412 are formed. Alternatively, curing tool 414 may begin curing shell layer 406 while three-dimensional structures are being formed (e.g., while propellant 404 is activated). In general, curing tool 414 may be used to cure shell layer 406 at any desired step of the three-dimensional structure formation process. However, the use of curing tool 414 is not required, and may not be used if shell layer 406 is able to retain three-dimensional structures without curing.

If desired, three-dimensional structures 412 may be used as microlenses in an imaging device. As previously described in connection with FIGS. 1-3, microlenses, such as microlenses 36, may be provided over pixels, such as pixels 22. In general, pixels 22 may be provided in array 20. The one or more microlenses formed over each pixel 22 of the array 20 may vary in shape, size, curvature, or other desired property to direct incident light to desired locations within pixels 22. The method described in connection with FIG. 4 may allow microlenses with varying shapes, sizes, and/or curvatures to be formed simultaneously. For example, the amount or concentration of propellant 404 used for forming three-dimensional structures 412 may be varied to provide microlenses with desired optical properties.

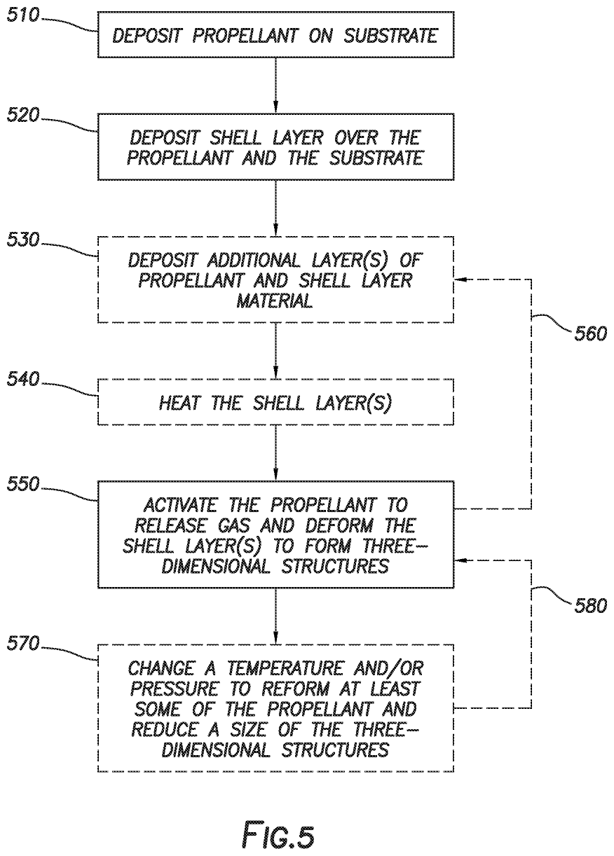

FIG. 5 is a flow chart of illustrative operations involved in forming three-dimensional structures on a substrate using propellant and shell layers.

At step 510, propellant 404 may be deposited on substrate 400 using deposition tool 402 (FIG. 4). Propellant 404 may be any desired decomposable compound, such as azobisisobutyronitrile (AIBN), another azo compound, or another nitrile compound. In general, propellant 404 may be deposited in a pattern or may be deposited in a continuous layer. If propellant 404 is deposited as a continuous layer, deposition tool 402 may perform patterning operations on propellant 404. Moreover, propellant 404 may have portions that contain different concentrations of a decomposable compound, different portions that contain different decomposable compounds, or may contain any desired mixture of materials in any desired concentrations.

At step 520, shell layer 406 may be deposited over propellant 404 and substrate 400 using deposition tool 402 (FIG. 4). Shell layer 406 may be formed from an elastomeric material, polymeric material, or any other deformable material.

At optional step 530, additional layers of propellant and additional shell layers may be deposited. These layers may be formed from the same material as propellant 404 and shell layer 406 or may be formed from different materials. As an example, additional layers may contain propellant requiring different activation energies and shell layers having different softening temperatures and/or different elastic moduli. Moreover, the additional shell layers may have varying thicknesses. More than one, more than two, more than five, more than ten, more than 100, less than 500, or more than 1000 additional layers of propellant and additional shell layers may be deposited. However, this is merely illustrative. In general, any number of layers of propellant and shell layers may be deposited and may be formed from any desired mixture of materials.

At optional step 540, activation tool 408 may heat shell layer 406 (FIG. 4) and any additional shell layers. For example, it may be desirable to heat polymeric shell layers past their glass transition temperatures so they may be deformed. However, shell layers of any material may be heated, if desired.

At step 550, activation tool 408 may apply energy (e.g., heat, ultraviolet energy, infrared energy, microwave energy, etc.) to propellant 404 and any additional propellant to release pockets of gas 410 under shell layer 406 and any additional shell layers (FIG. 4). If propellant and additional propellant have been deposited that require different activation energies, activation tool 408 may apply a first activation energy that is between the activation energies required by the propellant and the additional propellant and then apply a second activation energy that is greater than the activation energies required by the propellant and the additional propellant. This may form one or more layers of three-dimensional structures, such as three-dimensional structures 412 of FIG. 4.

As shown by optional path 560, additional layers of propellant and shell material may be deposited over the three-dimensional structures after the three-dimensional structures have been formed, and the additional propellant may be activated to form additional three-dimensional structures, as desired.

As previously discussed, curing tool 414 may cure three-dimensional structures 412 (FIG. 4) to maintain the structures in a desired shape either after the three-dimensional structures are formed or while they are being formed.

At optional step 570 a temperature and/or pressure of substrate 400, shell layer 406, or propellant 404 may be changed, resulting in some of propellant 404 to re-form, thereby reducing the size of volumes of gas 410. This, in turn, may cause three-dimensional structures 412 to decrease in size. By changing the temperature and/or pressure as needed, the size of three-dimensional structures 412 may be varied. This may be useful in forming microlenses or lenses with variable shapes and curvatures, as controllable, time-variable lenses may be formed. If it is desired to create variable three-dimensional structures in this way, propellant 404 may be formed from a material that decomposes reversibly. In this case, shell layer 406 may remain partially cured or uncured so that the shapes and/or sizes may be varied as desired.

As shown by optional path 580, propellant 404 may be reactivated to return the three-dimensional structures back to their previous sizes or to adjust the three-dimensional structures to another desired size. If desired, this the activation and re-forming of propellant 404 may occur continuously, allowing for continued adjustment of the shape and curvature of three-dimensional structures 412.

While the shapes of the three-dimensional structures of FIGS. 4 and 5 may be formed based on the concentration and materials used for propellant 404 and shell layer 406, this is merely illustrative. Any desired method of forming the three-dimensional structures in desired shapes may be used. For example, rigid surrounding shapes may be used to form the three-dimensional structures while propellant 404 is being activated. Upon curing, the three-dimensional structures may be maintained in shapes that correspond to the rigid surrounding shapes.

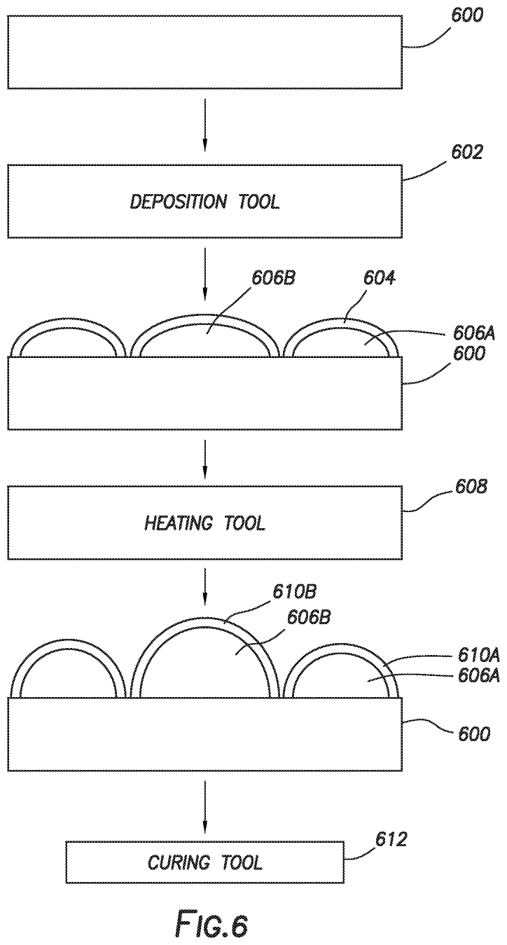

While FIGS. 4 and 5 illustrate embodiments in which propellant is used to deform overlying shell layers, it may be desired to form microlenses or other three-dimensional shapes without using propellant. A method of forming three-dimensional structures without using propellant is shown in FIG. 6.

As shown in FIG. 6, deposition tool 602 may be used to deposit a porous layer 604 onto substrate 600. As an example, substrate 600 may be glass. However, any desired material may be used for substrate 600. Deposition tool 602 may use ink jet printing, imprinting, 3D printing, or spin coating to deposit porous layer 604. If porous layer 604 is deposited using spin coating or another uniform deposition process, deposition tool 602 may also perform patterning. For example, deposition tool 602 may use lithography to remove portions of porous layer 604. However, these processes are merely illustrative. In general, deposition tool 602 may use any desired deposition and patterning processes to apply porous layer 604 to substrate 600.

In some embodiments, porous layer 604 may be formed from a low-density polymer. For example, porous layer 604 may be formed from polyethylene, polypropylene, or other low-density polymer. However, porous layer 604 may be formed from other low-density and/or porous materials if desired.

Due to the porosity of porous layer 604, a specific volume of gas may be trapped within porous layer 604 and/or between porous layer 604 and substrate 600. As shown in FIG. 6, the amount of gas trapped between different portions of porous layer 604 and substrate 600 may vary as a function of position along substrate 600. For example, volume of gas 606B may be larger than volume of gas 606A. However, this is merely illustrative. In general, porous layer 604 may be applied to trap any desired volume of gas between porous layer 604 and substrate 600 in any desired pattern along substrate 600.

After porous layer 604 has been deposited on substrate 600, heating tool 608 may be used to heat substrate 600 and/or porous layer 604. If porous layer 604 is formed from a polymer, the heat applied to porous layer 604 may soften the polymer and simultaneously expand volumes of gas 606. This may, in turn, expand porous layer 604, forming three-dimensional structures 610.

If an elastomeric material is used to form porous layer 604, heating tool 608 may only heat substrate 600, thereby increasing the volumes of gas 606 and forming three-dimensional structures 610. Alternatively, if porous layer 604 is formed from a polymer, heating tool 608 may also heat porous layer 604 above a glass transition temperature. In this way, the polymer used to form porous layer 604 may deform when the volumes of gas are expanded. However, this is merely illustrative. Heating tool 608 may heat porous layer 604 regardless of the material used to form porous layer 604, if desired. While heating substrate 600 and/or porous layer 604, the ambient pressure may also be reduced, thereby creating a vacuum that surrounds porous layer 604. The vacuum may further aid in causing the desired deformation of porous layer 604.

As shown in FIG. 6, volume of gas 606A may be smaller than volume of gas 606B. As a result, corresponding three-dimensional structure 610A may be smaller than three-dimensional structure 610B. Deposition tool 602 may deposit porous layer 604 to trap specific volumes of gas so that three-dimensional structures having desired shapes and/or curvatures may be formed. Alternatively or additionally, porous layer 604 may be formed from different materials along substrate 600 to form different three-dimensional structures. As an example, the portion of porous layer 604 corresponding to three-dimensional structure 610B may be more elastic than the portion of porous layer 604 corresponding to three-dimensional structure 610A, thereby creating two three-dimensional structures of different sizes. However, this is merely illustrative. In general, porous layer may be formed from any desired material and deposited in any desired method to form three-dimensional structures 610.

If desired, curing tool 612 may be used to maintain three-dimensional structures 610 in a three-dimensional shape. For example, if porous layer 604 is a polymer that has been heated above its glass transition temperature, curing tool 612 may harden porous layer 604 after three-dimensional structures 610 are formed. Alternatively, curing tool 612 may begin curing porous layer 604 while three-dimensional structures are being formed (e.g., while porous layer 604 and/or substrate 600 is heated). In general, curing tool 612 may be used to cure porous layer 604 at any desired step of the three-dimensional structure formation process. However, the use of curing tool 612 is not required, and may not be used if porous layer 604 is able to retain three-dimensional structures without curing.

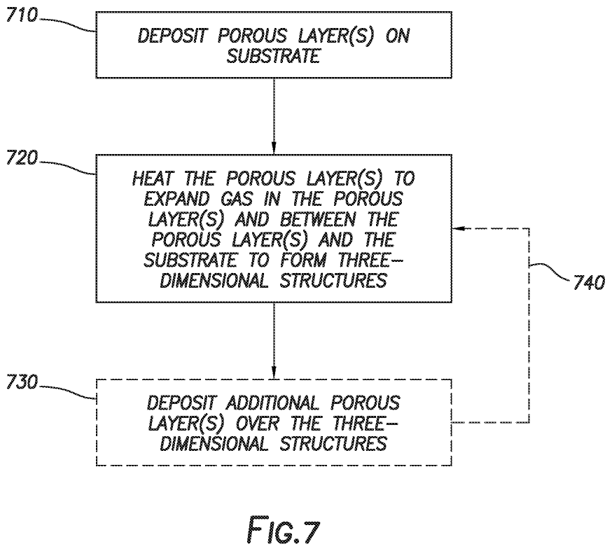

FIG. 7 is a flow chart of illustrative operations involved in forming three-dimensional structures on a substrate by heating porous materials.

At step 710, one or more porous layers 604 may be deposited on substrate 600 using deposition tool 602 (FIG. 6). The one or more porous layers may be formed from low-density polymers that trap volumes of gas 606 in the one or more porous layers and between the porous layers and substrate 600. For example, the one or more porous layers may be formed from different low-density polymers that deform at different glass transition temperatures. However, this is merely illustrative. Some or all of the one or more porous layers may be formed from the same material if desired.

At step 720, heating tool 608 (FIG. 6) may heat the one or more porous layers, thereby expanding the volumes of gas, deforming the one or more porous layers, and forming three-dimensional structures 610. The heating tool may be used to directly heat the one or more porous layers, may heat substrate 600, or may heat both the porous layers and the substrate.

At optional step 730, additional porous layers may be formed over the three-dimensional structures. These additional porous layers may be formed from the same material as porous layer 604 or may be formed from different materials. As an example, additional porous layers may have different softening temperatures and/or different elastic moduli. Moreover, the additional porous layers may have varying thicknesses. More than one, more than two, more than five, more than ten, more than 100, less than 500, or more than 1000 additional layers of propellant and shell material may be deposited. However, this is merely illustrative. In general, any number of porous layers may be formed on substrate 600.

As illustrated by optional path 740, the additional porous layers may be heated to form additional three-dimensional structures.

As previously discussed, curing tool 612 may cure three-dimensional structures 610 (FIG. 6) to maintain the three-dimensional structures in desired shapes and/or curvatures either after the three-dimensional structures are formed or while they are being formed.

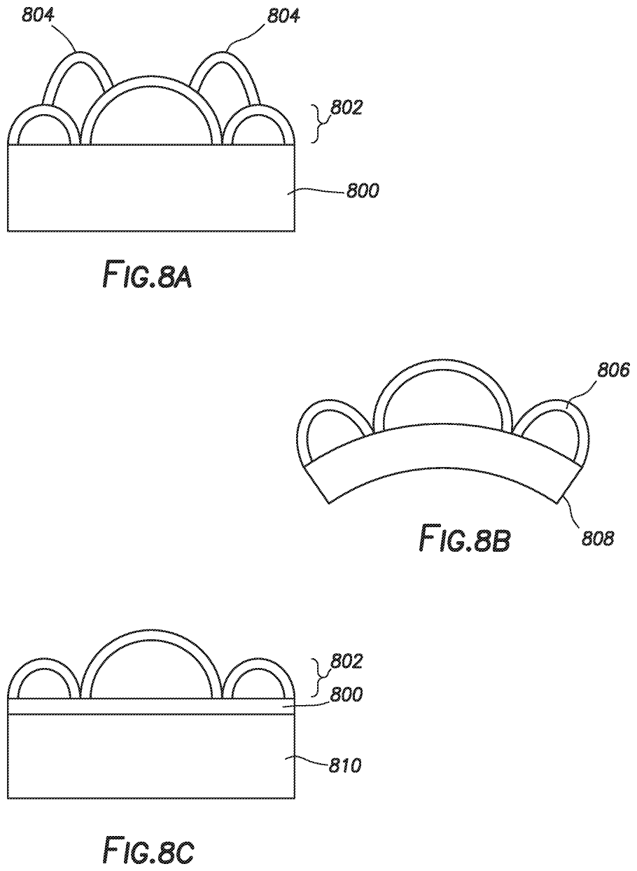

While the methods of FIGS. 4-7 have been described as forming one or more layers of three-dimensional structures over a planar substrate, this is merely illustrative. In general, any desired number of stacked three-dimensional structures may be formed of substrates of any desired shape. Illustrative embodiments are shown in FIG. 8.

As shown in FIG. 8A, two layers of three-dimensional structures may be formed on substrate 800. In one embodiment, the first layer 802 of three-dimensional structures may be formed according to the method described in FIGS. 4 and 5 or may be formed according to the method described in FIGS. 6 and 7.

For example, following the formation of first layer 802 using the method of FIGS. 4 and 5, one or more additional layers of propellant and shell material may be applied to first layer 802 using a deposition tool such as deposition tool 402 (e.g., as shown by optional path 560 of FIG. 5). The additional propellant may then be activated to form additional three-dimensional structures 804. This may be repeated to form more than two layers of three-dimensional structures, if desired. In general, any number of layers of three-dimensional structures may be formed.

Alternatively, following the formation of first layer 802 using the method of FIGS. 6 and 7, one or more additional porous layers may be deposited over first layer 802 using a deposition tool such as deposition tool 602 (e.g., as shown by optional path 740 of FIG. 7). The additional porous layer(s) may then be heated as previously described in connection with FIG. 6 to expand volumes of gas and deform the porous layer(s) to form additional three-dimensional structures 804. This may be repeated to form more than two layers of three-dimensional structures, if desired. In general, any number of layers of three-dimensional structures may be formed.

Although the materials that form the additional layer(s) of three-dimensional structures have been described as being deposited after the formation of the first layer of three-dimensional layers, this is merely illustrative. If desired, more than one layer of propellant 404 and shell layer 406 of FIG. 4 may be stacked prior to the activation of propellant 404 (e.g., as shown in optional step 530 of FIG. 5). In this way, multiple layers of three-dimensional structures may be formed simultaneously or substantially simultaneously upon the activation of the multiple layers of propellant 404. Moreover, propellants with different activation temperatures may be used to form three-dimensional shapes sequentially (e.g., as the temperatures applied to the layers of propellant are gradually increased).

Similarly, more than one porous layer 604 may be stacked on substrate 600 of FIG. 6 (e.g., as shown in step 720 of FIG. 7). In this way, multiple layers of three-dimensional structures may be formed simultaneously or substantially simultaneously upon the heating of the multiple porous layers.

Moreover, the methods shown in FIGS. 4 and 5 of using a propellants and shell layers to form three-dimensional structures and the methods shown in FIGS. 6 and 7 of using low-density materials to form three-dimensional structures may be used to form different portions of the three-dimensional structures shown in FIG. 8A. For example, first layer 802 may be formed by heating a low-density material, while additional three-dimensional structures 804 may be formed by activating a propellant to deform a shell layer. However, this is merely illustrative. Any combination of using propellants, shell layers, and porous layers may be used, if desired.

As shown in FIG. 8B, three-dimensional structures 806 may be formed on curved substrate 808. In particular, propellant and shell layer(s) or porous layer(s) may be applied to curved substrate 808 using three-dimensional printing techniques. In this way, complex three-dimensional structures may be formed on non-planar substrates using the methods described in connection with FIGS. 4-7.

In the embodiment shown in FIG. 8C, one or more layers of three-dimensional structures 802 and substrate 800 may be formed over component 810. Component 810 may be an image sensor pixel, such as pixel 22, for example. As previously described, three-dimensional structures 802 may be formed with different shapes and curvatures to form microlenses over pixel 22. This may allow light incident on pixel 22 to reach desired photosensitive regions. For example, three-dimensional structures 602 may have toroidal shapes to form toroidal microlenses that direct light to the edges of pixel 22, may have semispherical shapes with different curvatures that allow pixel 22 to be used for phase detection operations, or may have other shapes to provide additional optical functionalities for pixel 22.

When three-dimensional structures 802 are used as microlenses in an image sensor, three-dimensional structures 802 may have semispherical, hemispherical, or semi-cylindrical shapes with diameters of less than 10 microns, less than 1 mm, more than 1 micron, less than 500 microns, or any other desired size. Three-dimensional structures 802 may have larger diameters if each three-dimensional structures is used as a microlens for a respective pixel or if substrate 800 is configured to cover more than one pixel in an array of pixels, however. Additionally, the microlenses may have other shapes, if desired.

While three-dimensional structures 802 have been described as being used as microlenses for image sensor pixels, this is merely illustrative. In general, three-dimensional structures 802 may be used to form any desired structure on substrate 800.

For example, three-dimensional structures 802 may form a secondary lens on top of a primary lens in a light field camera. In this case, the primary lens may be formed from substrate 800, component 810, or another component within the light field camera. The secondary lens formed from three-dimensional structures 802 may increase the spatial resolution of a camera (e.g., at the expense of angular resolution), by allowing more light to reach the image sensor(s) of the light field camera. Because of the increase in spatial resolution and the increase in light field information, images taken by the light field camera may be processed after a photograph or video is taken.

Although three-dimensional structures 802 have been described as forming optical components (e.g., microlenses for image sensor pixels or lenses for a camera), the three-dimensional structures are not limited to use in optical devices. For example, three-dimensional structures 802 may be used in mechanical or fluidic devices.

In one embodiment, three-dimensional structures 802 may be formed within bioanalytical devices. In particular, bioanalytical devices typically contain cells on a substrate, with each cell capable of receiving a sample for testing. The sample may be a fluid or a solid, for example. Three-dimensional structures 802 may form the cells within the bioanalytical devices. As an example, the space between three-dimensional structures 802 may receive the samples for testing. Alternatively, three-dimensional structures 802 may be formed with shapes that are received test samples directly, such as cylindrical shapes, rectangular prism shapes, or any other desired shapes. When used in bioanalytical devices, three-dimensional structures 802 may be larger than those used as image sensor pixel microlenses. For example, cylindrical three-dimensional structures 802 in bioanalytical devices may have diameters of more than 1 mm, more than 5 mm, more than 10 mm, less than 20 mm, or more than 15 mm, as examples. The sizes of the three-dimensional structures may be modified as desired using different concentrations of propellant and polymer materials as described above in connection with FIGS. 4-7.

In another embodiment, the formation of three-dimensional structures 802 may be used for simulating structures (e.g., as a replacement for three-dimensional printing operations). By stacking multiple layers of propellant and polymer with varying concentrations and activation temperatures, complex three-dimensional geometries may be formed. For example, more than five layers, more than 10 layers, more than 50 layers, fewer than 100 layers, and more than 250 layers of propellant and polymer may be used to form complex three-dimensional geometries. However, these applications are merely illustrative. In general, three-dimensional structures 802 may be used in any desired apparatus, device, or application.

Various methods of forming three-dimensional structures on a surface that increase flexibility of the shapes, sizes, and other characteristics of the three-dimensional structures have been described. Various embodiments have also been described in which the three-dimensional structures form microlenses for image sensor pixels, lenses for cameras, bioanalytical devices, or complex three-dimensional structure simulations.

In various embodiments, a propellant may be deposited onto a substrate that overlaps a photosensitive region of an imaging sensor pixel. A shell layer may then be deposited over the propellant and the substrate, and the propellant may be activated to release a gas and form three-dimensional microlens structures in the shell layer that overlap the photosensitive region. While activating the propellant, the shell layer may be cured to maintain the three-dimensional microlens structures in desired shapes. The propellant may be deposited as first and second propellant portions that have respective first and second concentrations of propellant material. The first concentration of propellant material may be different from the second concentration of propellant material. The first and second propellant portions may be deposited using ink jet printing, imprinting, and three-dimensional printing, as examples.

The propellant may alternatively be patterned into first and second propellant portions after the propellant has been deposited on the substrate. Processes such as lithography may be used to pattern the propellant into the first and second propellant portions.

The propellant may be an azo compound that is deposited onto the substrate. In particular, the propellant may be azobisisobutyronitrile, if desired. The shell layer may be an elastomeric material or a polymeric material. In some cases, the shell layer may have a glass transition temperature at which the shell layer softens. The shell layer may be heated to a temperature that is greater than the glass transition temperature prior to the activation of the propellant to soften the shell layer. While heating the shell layer, the ambient pressure may also be reduced, thereby creating a vacuum surrounding the shell layer, which may further aid in causing the desired deformation of the shell layer.

Activating the propellant may include decomposing a portion of the propellant using an activation tool to apply energy to the propellant to form three-dimensional microlens structures having a first diameter. After decomposing the portion of the propellant, a temperature and/or pressure of the imaging sensor pixel may be changed to re-form some of the propellant to adjust the three-dimensional microlens structures to have a second diameter that is less than the first diameter.

In various embodiments, a propellant may be deposited on a substrate, a shell layer may be deposited over the propellant and the substrate, and the propellant may be activated to release a gaseous byproduct and from three-dimensional structures in the shell layer. If desired, additional propellant and one or more additional shell layers may be deposited on the shell layer, and both the propellant and the additional propellant may be activated. The propellant may be formed from a first material having a first activation energy and the additional propellant may be formed from a second material having a second activation energy that is different from the first activation energy.

The propellant and the additional propellant may first be exposed to a first amount of energy that is greater than the first activation energy and less than the second activation energy to form a first set of three-dimensional structures. After the propellant and the additional propellant have been exposed to the first amount of energy, the additional propellant may be exposed to a second amount of energy that is greater than the second activation energy to form a second set of three-dimensional structures. The deposited shell layer may be a first layer having a first thickness and one of the additional shell layers may be a second layer having a second thickness that is different from the first thickness.

In various embodiments, at least one porous layer may be deposited on a substrate, thereby trapping volumes of gas in the at least one porous layer. The substrate may be heated to expand the volumes of gas, and the at least one porous layer may be heated past a softening point to deform the at least one porous layer and form the three-dimensional structures when the volumes of gas expand. After heating the substrate, the at least one porous layer may be cured to maintain the three-dimensional structures in desired shapes. If desired, the at least one porous layer may be a first polymer layer with a first thickness and a second polymer layer with a second thickness that is different from the first thickness. Both the first and second polymer layers may be heated to deform the first and second polymer layers and form first and second layers of three-dimensional structures when the volumes of gas expand.

The foregoing is merely illustrative of the principles of this invention and various modifications can be made by those skilled in the art without departing from the scope and spirit of the invention.

What is claimed is:

1. A method of forming an imaging sensor pixel having a photosensitive region, the method comprising:
depositing a propellant onto a substrate that overlaps the photosensitive region;
depositing a shell layer over the propellant and the substrate; and
activating the propellant to release a gas and form three-dimensional microlens structures in the shell layer that overlap the photosensitive region.

2. The method defined in claim 1 further comprising:
while activating the propellant, curing the shell layer to maintain the three-dimensional microlens structures in the shell layer.

3. The method defined in claim 1 wherein depositing the propellant onto the substrate comprises depositing a first propellant portion with a first concentration of propellant material and a second propellant portion with a second concentration of propellant material that is different from the first concentration of propellant material.

4. The method defined in claim 3 wherein depositing the first propellant portion and the second propellant portion comprises depositing the first and second propellant portions using a deposition method selected from the group of methods consisting of: ink jet printing, imprinting, and three-dimensional printing.

5. The method defined in claim 1 further comprising:
after depositing the propellant onto the substrate, patterning the propellant into a first propellant portion and a second propellant portion.

6. The method defined in claim 5 wherein patterning the propellant comprises using a lithography process to pattern the propellant into the first and second propellant portions.

7. The method defined in claim 1 wherein depositing the propellant onto the substrate comprises depositing a nitrile material onto the substrate.

8. The method defined in claim 1 wherein depositing the shell layer over the propellant and the substrate comprises depositing an elastomeric material over the propellant and the substrate.

9. The method defined in claim 1 wherein depositing the shell layer over the propellant and the substrate comprises depositing a polymeric material over the propellant and the substrate.

10. The method defined in claim 9 wherein the polymeric material has a glass transition temperature at which the polymeric material softens, the method further comprising:
after depositing the polymeric material over the propellant and the substrate, heating the polymeric material to a temperature greater than the glass transition temperature.

11. The method defined in claim 1 wherein activating the propellant comprises decomposing a portion of the propellant using an activation tool to apply energy to the propellant and form three-dimensional microlens structures having a first diameter in the shell layer.

12. The method defined in claim 11 further comprising:
after decomposing the portion of the propellant, changing a temperature and pressure of the imaging sensor pixel to re-form at least some of the propellant to adjust the three-dimensional microlens structures to have a second diameter that is less than the first diameter.

13. A method of forming three-dimensional structures on a substrate, the method comprising:
depositing a propellant onto a substrate;
depositing a shell layer over the propellant and the substrate; and
activating the propellant to release a gaseous byproduct and form the three-dimensional structures in the shell layer.

14. The method of claim 13 further comprising:
after depositing the shell layer, depositing additional propellant and one or more additional shell layers on the shell layer, wherein activating the propellant comprises activating both the propellant and the additional propellant.

15. The method of claim 14 wherein depositing the propellant comprises depositing first material having a first activation energy and wherein depositing the additional propellant comprises depositing second material having a second activation energy that is different from the first activation energy.

16. The method of claim 15 wherein activating the propellant comprises:
exposing the propellant and the additional propellant to a first amount of energy that is greater than the first activation energy and less than the second activation energy to form a first set of three-dimensional structures, and
after exposing the propellant and the additional propellant to the first amount of energy, exposing the additional propellant to a second amount of energy that is greater than the second activation energy to form a second set of three-dimensional structures.

17. The method defined in claim 16 wherein depositing the shell layer comprises depositing a first layer with a first thickness and wherein depositing the one or more additional shell layers comprises depositing a second layer with a second thickness that is different from the first thickness.

18. A method of forming an item having three-dimensional structures on a substrate, the method comprising;
depositing at least one porous layer on a substrate thereby trapping volumes of gas in the at least one porous layer;
heating the substrate to expand the volumes of gas; and
while heating the substrate, heating the at least one porous layer past a softening point to deform the at least one porous layer and form the three-dimensional structures when the volumes of gas expand.

19. The method defined in claim 18 further comprising:
after heating the substrate, curing the at least one porous layer to maintain the three-dimensional structures in desired shapes.

20. The method defined in claim 19 wherein depositing the at least one porous layer comprises depositing a first polymer layer with a first thickness and a second polymer layer with a second thickness that is different from the first thickness and wherein heating the at least one porous layer comprises heating the first and second polymer layers to deform the first and second polymer layers and form first and second layers of three-dimensional structures when the volumes of gas expand.
